(19) United States
(12) Patent Application Publication
(10) Pub. No.: US 2025/0012748 A1
(43) Pub. Date: Jan. 9, 2025

(54) SYSTEM AND METHOD FOR FLUID SENSING

(71) Applicant: MEDISENS WIRELESS, INC., Santa Clara, CA (US)

(72) Inventors: Nitin Raut, Sunnyvale, CA (US); Luke Stevens, Santa Clara, CA (US)

(21) Appl. No.: 18/742,764

(22) Filed: Jun. 13, 2024

Related U.S. Application Data
(63) Continuation of application No. 17/666,394, filed on Feb. 7, 2022, now abandoned.
Application No. 17/666,394 is a continuation of application No. 14/404,909, filed on Dec. 1, 2014, now abandoned.
(60) Provisional application No. 61/717,032, filed on Oct. 22, 2012.
(60) Provisional application No. 61/653,071, filed on May 30, 2012.
(60) Provisional application No. 61/653,307, filed on May 30, 2012.
(60) Provisional application No. 61/653,310, filed on May 30, 2012.
(60) Provisional application No. 61/653,313, filed on May 30, 2012.

(51) Int. Cl. G01N 27/12; G01L 1/18; G01N 27/04; G01N 27/22; G01R 35/00

(52) U.S. Cl. CPC G01N 27/121; G01L 1/18; G01N 27/048; G01N 27/223; G01R 35/00

(57) ABSTRACT

A system and method for moisture sensing and methods for making and using same. The present disclosure describes a fluid sensing array that comprises a first and second set of conducting lines with a fluid layer disposed between the first and second set of conducting lines. Proximate intersections of the sets of conducting lines define a plurality of sensing regions. Reading the plurality of sensing regions may provide for calculating a value for fluid volume present, a value for surface area where fluid is present, or a determination of the identity, class or a characteristic of a fluid present.

### CROSS-REFERENCE TO RELATED APPLICATIONS

This application claims the benefit of U.S. Provisional Application No. 61/653,071 filed May 30, 2012 entitled “Pressure Signature Based Biometric Systems and Methods”; claims benefit of U.S. Provisional Application No. 61/653,307, filed May 30, 2012 entitled “Decoupling Using Forward/Backward Coupling”; claims benefit of U.S. Provisional Application 61/653,310, filed May 30, 2012 entitled “Wearable Sensor Assembly”; claims the benefit of U.S. Provisional Application No. 61/653,313, filed May 30, 2012 entitled “System and Method for Environment Variation Handling”, and claims the benefit of U.S. Provisional Application No. 61/717,032, filed Oct. 22, 2012 entitled “Sensor and Array Assembly for Moisture Detection and Volume Estimation”, which applications are hereby incorporated herein by reference in their entirety. This application is also related to PCT application PCT/US2013/______ filed May 30, 2013, by the same applicant, and entitled PRESSURE SIGNATURE BASED BIOMETRIC SYSTEMS, SENSOR ASSEMBLIES AND METHODS, which application is incorporated herein by reference in its entirety.

### BACKGROUND

The use of sensors is a well known practice to gather a wide variety of data measuring properties of substances. For example, sensors may be operable to sense the presence of certain substances, calculate the volume of a substance, identify a substance, determine physical characteristics of a substance, or the like.

Sensors may be used in medical applications to sense bodily fluids such as blood, urine or perspiration. Unfortunately, conventional fluid sensors fail to provide for accurate and cost-effective sensing of fluids, and are unable to be adapted to specialized sensing environments such as medical applications. Accordingly, improved fluid sensors, methods of calibrating fluid sensors, and methods of obtaining data from fluid sensors are needed in the art.

### SUMMARY

The present disclosure describes one embodiment of a fluid sensing array that comprises a first and second set of conducting lines with a fluid layer disposed between the first and second set of conducting lines. Proximate intersections of the sets of conducting lines define a plurality of sensing regions. Reading the plurality of sensing regions may provide for calculating a value for fluid volume present, a value for surface area where fluid is present, or a determination of the identity, class or a characteristic of a fluid present.

Additional embodiments describe methods for calibrating a fluid sensor, which include obtaining a reading from the array at a dry state, and obtaining a plurality of readings from the sensor array when the array is exposed to known volumes of a fluid. A transfer curve or function may be generated by calculating a general function of each set of readings or by calculating a total sum of each set of readings.

Further embodiments, described herein include variations of a sensor array, which may include concentric electrodes, an array of electrode dots, and an array of elongated electrodes, which are disposed surrounded by a conductive material.

### BRIEF DESCRIPTION OF THE DRAWINGS

FIG. 1a is an exemplary top view drawing illustrating an embodiment of a sensor array.

FIG. 1b is an exemplary first side view drawing illustrating the embodiment of the sensor array in FIG. 1a.

FIG. 1c is an exemplary close-up of the sensor array depicted in FIG. 1b.

FIG. 1d is an exemplary second side view drawing illustrating the embodiment of the sensor array in FIG. 1a.

FIG. 1e is an exemplary close-up of the sensor array depicted in FIG. 1d.

FIG. 2a is an exemplary top view drawing illustrating another embodiment of a sensor array.

FIG. 2b is an exemplary first side view drawing illustrating the embodiment of the sensor array in FIG. 2a.

FIG. 3 is an exemplary top view drawing illustrating another embodiment of a sensor array.

FIG. 4 an exemplary top view drawing illustrating a further embodiment of a sensor array.

FIG. 5 is top-level drawing depicting an embodiment of a system for fluid sensing.

FIG. 6 is a block diagram illustrating an embodiment of a data acquisition unit.

FIG. 7 is an exemplary flow chart illustrating an embodiment of a method for moisture sensing.

FIG. 8 is an exemplary flow chart illustrating an embodiment of a method for calibrating a moisture sensor.

FIG. 9 is an exemplary flow chart illustrating another embodiment of a method for calibrating a moisture sensor.

FIG. 10a depicts a method of determining fluid volume in accordance with one embodiment.

FIG. 10b depicts a method of determining fluid volume in accordance with another embodiment.

It should be noted that the figures are not drawn to scale and that elements of similar structures or functions are generally represented by like reference numerals for illustrative purposes throughout the figures. It also should be noted that the figures are only intended to facilitate the description of the preferred embodiments. The figures do not illustrate every aspect of the described embodiments and do not limit the scope of the present disclosure.

### DETAILED DESCRIPTION OF THE PREFERRED EMBODIMENTS

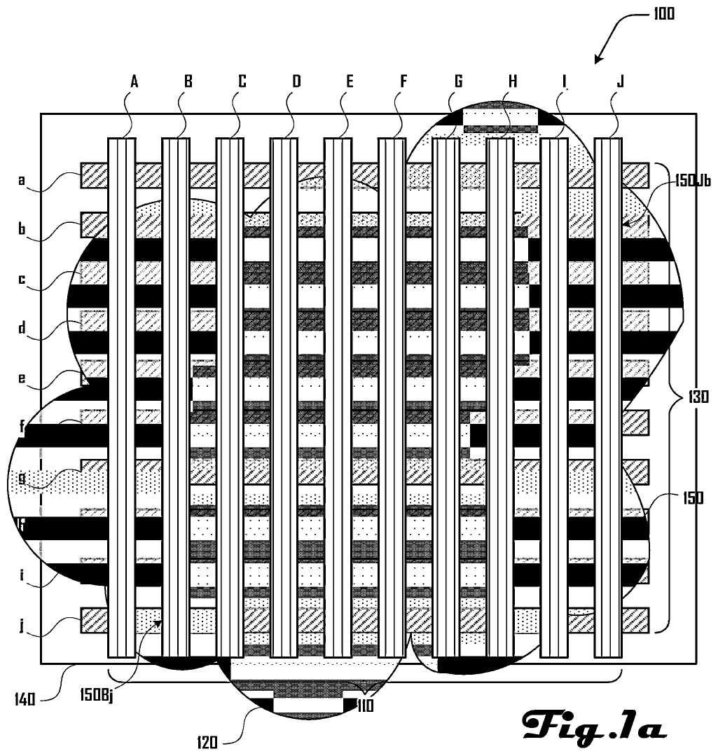

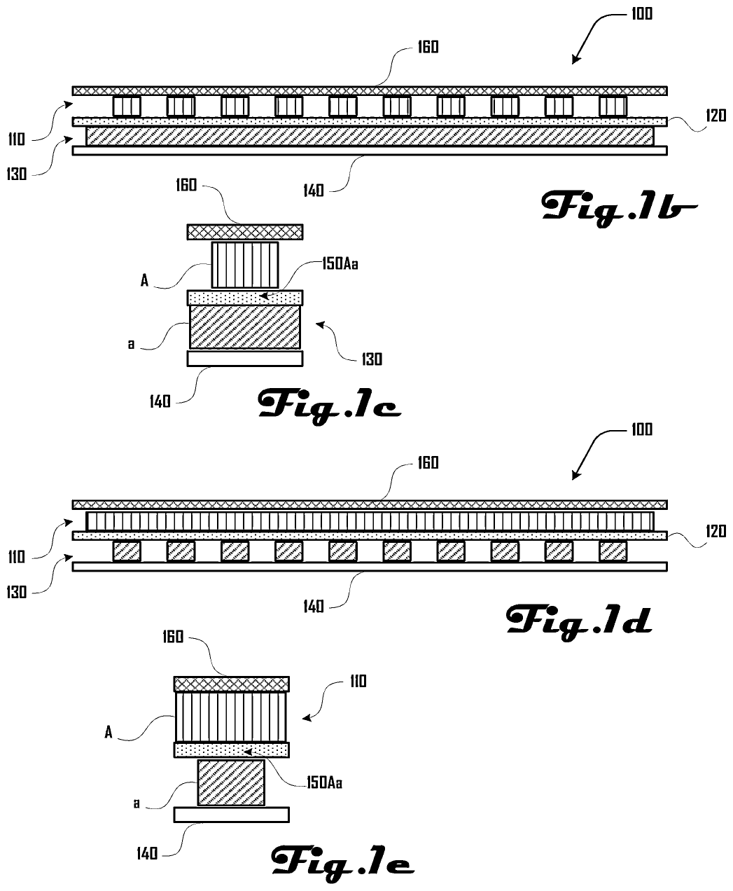

Since currently-available moisture systems fail to effectively provide for accurate detection of fluid, improved systems and methods that provide for moisture sensing can prove desirable and provide a basis for a wide range of applications, such as providing a value for fluid volume present, providing a value for surface area where fluid is present, providing a determination of the identity, class or characteristic of a fluid, and providing for detection of motion, position or other characteristic of a subject wearing such a sensor. Such results can be achieved, according to one embodiment disclosed herein, by a moisture sensing array 100 as illustrated in FIGS. 1a-1e.

The moisture sensing array 100 comprises a first and second set of conducting lines 110, 130 with a fluid layer 120 disposed between the first and second set of conducting lines 110, 130. A fluid barrier layer 140 is disposed facing the second set of conducting lines 130 and a buffer layer 160 may be disposed facing the first set of conducting lines 110.

Accordingly, a portion of the moisture sensing array 100 may be defined by plurality of layers. The buffer layer 160 may be layered facing the first set of conducting lines 110 with the first set of conducting lines 110 being layered between the fluid layer 120 and the buffer layer 160. The fluid layer 120 can be layered between the first and second conducting lines 110, 130. The second set of conducting lines 130 may be layered between the fluid layer 120 and the fluid barrier layer 140. The fluid barrier layer 140 may be layered facing the second set of conducting lines 130.

In some embodiments, the first set of conducting lines 110 may be spaced apart, substantially parallel and extend in a first direction and the second set of conducting lines 130 may be spaced apart, substantially parallel and extend in a second direction that is substantially perpendicular to the first direction of the first set of conducting lines 110. Each of the conducting lines of the first set 110 may disposed proximate to each of the conducting lines of the second set 130, which defines a plurality of sensing regions 150. Each sensing region 150 may be defined by a region where one of the first and second set of conducting lines 110, 130 are proximate and defined by a portion of the fluid layer 120.

For example, FIG. 1 depicts the first set of conducting lines 110 labeled capital A-J and the second set of conducting lines 130 labeled lower case a-j. Sensing region 150Jb is defined by the proximate junction of conducting line “J” and conducting line “b”; sensing region 150Bj is defined by the proximate junction of conducting line “B” and conducting line “j”; and sensing region 150Aa is defined by the proximate junction of conducting line “A” and conducting line “a” as depicted in FIGS. 1c and 1e. The plurality of sensing regions 150 can collectively define a sensing array of sensing regions 150.

The first and second set of conducting lines 110, 130 may comprise any suitable conductive material, and may be any suitable size or shape. For example, in some embodiments, the conducting lines 110, 130 may be elongated and flat, rounded, rectangular or the like. Additionally, the conducting lines 110, 130 may of uniform or non-uniform size, shape, material or spacing. While various depicted embodiments depict conducting line sets 110, 130 having ten lines each, a moisture sensing array 100 may have any suitable number of conducting lines in a set, cither uniform or non uniform.

In some embodiments, the moisture sensing array 100 may be flexible or rigid. For example, in some embodiments, it may be desirable for the moisture sensing array 100 to be flexible so that the array 100 can confirm to various shapes. In some embodiments, the array 100 may define a portion of bedding, a diaper, a bandage, pants, a shirt, a hat, socks, and gloves, or the like. As discussed in more detail herein, this may be desirable so that moisture generated by a human subject may be sensed and tracked in terms of either volume, surface area, and/or position on the array.

The fluid layer 120 may be a material operable to change in electrical properties(s) (e.g., resistive properties, capacitive properties, or inductive properties) in response to the presence of a fluid such as a liquid or gas. For example, in some embodiments, the fluid layer 120 may comprise a polyaniline-based conducting polymer doped with weak acid dopants.

In various embodiments, the fluid barrier layer 140 may be a material that is impermeable to various fluids. For example, the fluid barrier layer 140 may configured to be impermeable to a fluid that affects one or more electrical properties(s) of the fluid layer 120. This may be desirable because the fluid barrier layer 140 may thereby hold a target fluid in the fluid layer 120 to enable measurement and/or sensing of the fluid as described herein.

In various embodiments, the buffer layer 160 may comprise a material that provides a holding capacity for a fluid within the fluid barrier layer 140. The material of the buffer layer 160 may be selected with a desired moisture holding capacity so as to extend the active sensing range of the array 100. In various embodiments, the buffer layer 160 may provide an entry for fluid into the array 100 and into the fluid layer 120.

In some embodiments, the buffer layer 140 may provide for fluid conditioning. For example, the buffer layer 140 may be configured to filter out particulate matter, may be configured to remove matter dissolved in a fluid, may be configured to separate one type or class of fluid from another, or the like.

The buffer layer 140 may also serve as a comfort layer when the array 100 is used by a subject. For example, where the array is incorporated into objects such as bedding, a diaper, a bandage, pants, a shirt, a hat, socks, or gloves, it may be desirable for the buffer layer to comprise a soft material so that wearability of the article is improved.

For example, the array 100 may be substantially planar with the buffer layer 160 in contact with the skin of a human subject. When the subject sweats (i.e., excretes fluid), the fluid can pass into the buffer layer 160 and into the fluid layer 120, where the sweat fluid is sensed and quantified as described herein.

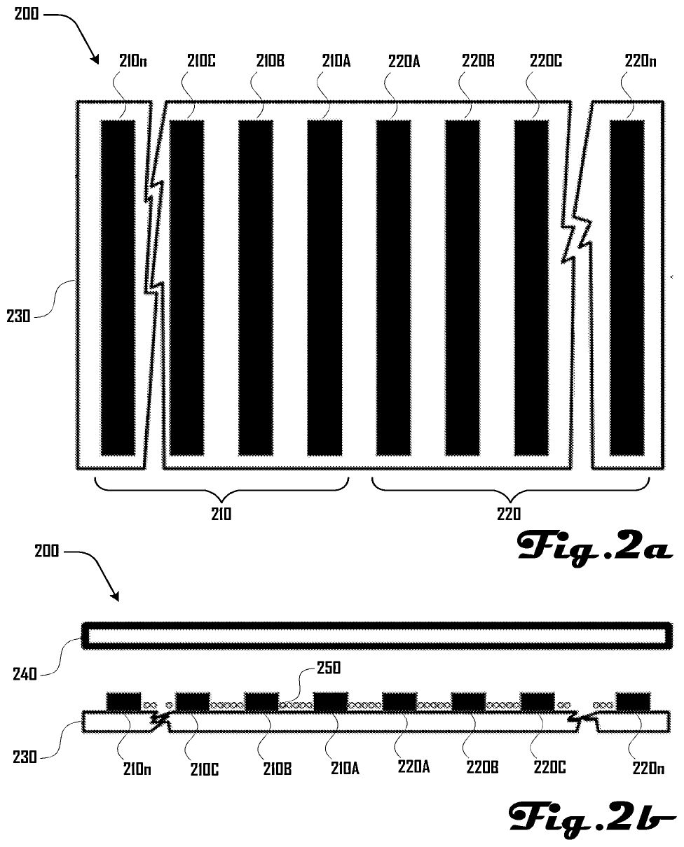

FIGS. 2a, 2b, 3 and 4 depict moisture sensing arrays 200, 300, 400 in accordance with further embodiments. Turning to FIGS. 2a and 2b, the moisture sensing array 200 can comprise a moisture barrier layer 230 with a first set of conducting lines 210 disposed on one side of the moisture barrier layer 230, and a second set of conducting lines 220 disposed on another side of the moisture barrier layer 230. The first set of conducting lines 210 is labeled as lines 210A-210n and the second set of conducting lines 220 is labeled as 220A-n. As depicted in FIG. 2b, the array 200 may comprise a buffer layer 240.

Further disposed on the moisture barrier layer 230 and between each of the conducting lines 210, 220 is a fluid activated material 250, which may comprise a plurality of conductive particles that change in electrical characteristic(s) when exposed to a fluid. For example, the fluid activated material 250 may be non-conducting or of fixed conductance in a dry state, and the conductance of the material 250 may change when wet. This may be desirable in embodiments where detection of a non-conductive fluid is required.

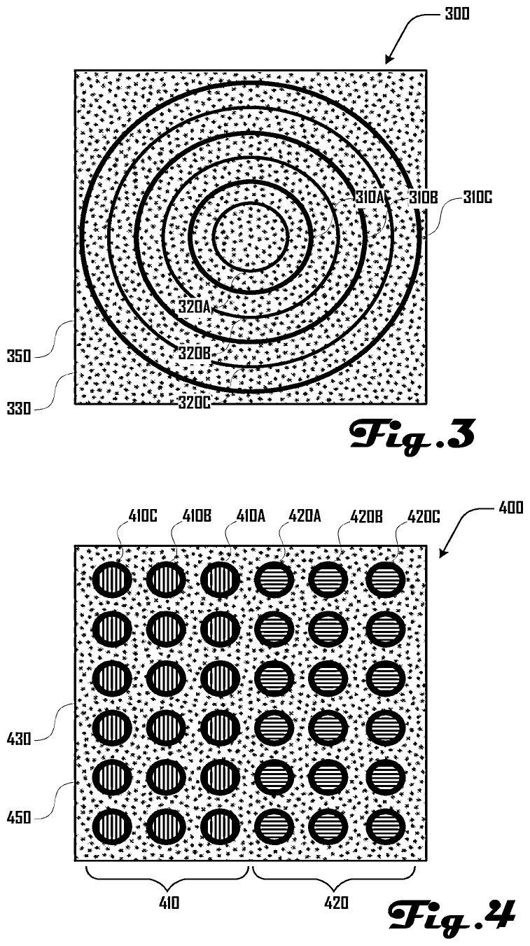

FIG. 3 depicts a moisture sensing array 300 comprising a plurality of concentric electrodes 310, 320 having a fluid activated material 350 disposed therebetween, with the electrodes 310, 320 and material 350 disposed on a moisture barrier layer 330. First and second sets of electrodes 310, 320 may be alternated concentrically in some embodiments. For example, as shown in FIG. 3, the largest electrode 310C may be proximate to smaller electrode 320C, with smaller electrode 320C proximate to still smaller electrode 310B. Similarly, smallest electrode 320A may be proximate to next smallest electrode 310A, which is proximate to third smallest electrode 320B.

FIG. 4 depicts a fluid sensing array 400 comprising a plurality of electrodes 410, 420 disposed on a fluid barrier 430 with a fluid activated material 450 disposed on the fluid barrier 430 between the electrodes 410, 420. In various embodiments, the electrodes 410, 420 may be grouped in columns and rows, with the first set of electrodes 410 on one portion of the fluid barrier 430 and the second set of electrodes 420 on another portion of the fluid barrier 430. For example, one row may sequentially include three first electrodes 410C, 410B, 410A and then three second electrodes 420A, 420B, 420C.

The example embodiments of a sensor array 100, 200, 300, 400 depicted herein should not be construed to limit the possibility of further embodiments. In some embodiments any of the components may be absent, or may be present in plurality. For example, in some embodiments a buffer layer 160, 240 may be absent. In another example, there may be a plurality of conducting line sets 110, 120. In a still further example, a plurality of sensor arrays 100 and/or conducting line sets 110, 120 may be layered together. In yet another example, the fluid layer may be absent 120, when conductive fluids such as blood, urine or the like is desired for detection.

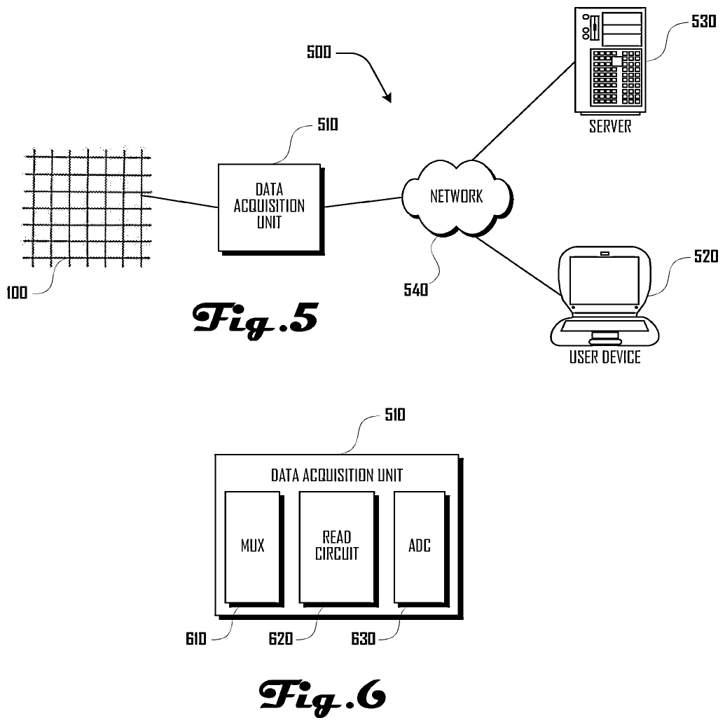

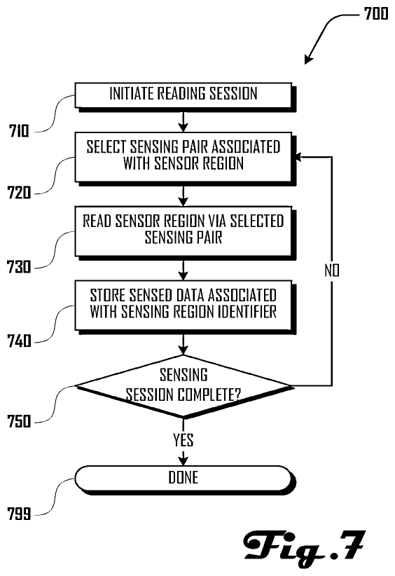

Turning to FIG. 5, a moisture sensing system 500 is shown as including at least one sensor array 100 operably connected to a data acquisition unit 510, a user device 520, and a server 530 that are operably connected via a network 540.

The user device 520, server 530, and network 540 each can be provided as conventional communication devices of any type. For example, the user device 520 may be a laptop computer as depicted in FIG. 5; however, in various embodiments, the user device 520 may be various suitable devices including a tablet computer, smart-phone, desktop computer, gaming device, or the like without limitation.

Additionally, the server 530 may be any suitable device, may comprise a plurality of devices, or may be a cloud-based data storage system. In various embodiments, the network 540 may comprise one or more suitable wireless or wired networks, including the Internet, a local-area network (LAN), a wide-area network (WAN), or the like. Additionally, the sensor array 100 can be operably connected to a data acquisition unit 510 via one or more wire, wirelessly, via a network like the network 540, or in some embodiments, via the network 540.

In various embodiments, there may be a plurality of any of the user device 520, the server 530, data acquisition unit 510, or sensor array 100. For example, in an embodiment, there may be a plurality of users that are associated with one or more user devices 520, and the users (via user devices 520) and the server 530 may communicate with or interact with one or more data acquisition unit 510 and sensor array 100. Data obtained from the sensor array 100 or data acquisition unit 510 may be processed and or stored at the user device 520, server 530, or the like.

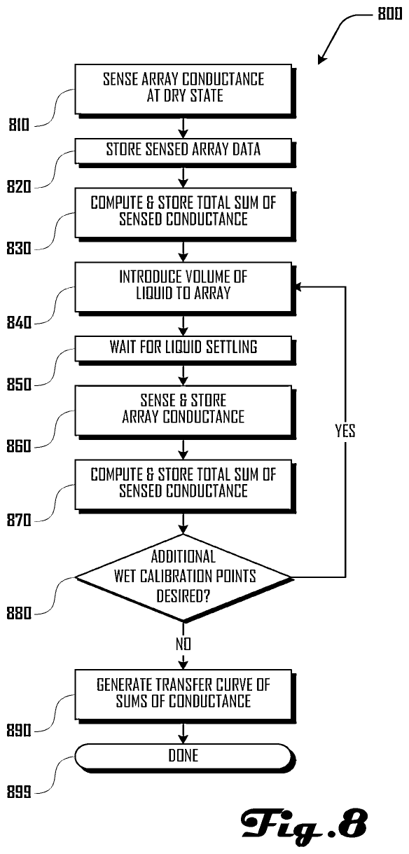

FIG. 6 is a block diagram illustrating an embodiment of the data acquisition unit 510 depicted in FIG. 5, which comprises a multiplexer 610, a read circuit 620 and an analog-to-digital converter 630. The multiplexer 510 may obtain a signal (e.g., an analog voltage) from the array 100 and provide the signal to the read circuit 620, and the read signal can be converted to a digital signal by the analog-to-digital converter 630 and the digital signal may be provided to a computation point, which may include one or both of the user device 520, server 530 or any other suitable computation device. In some embodiments, computation may occur at the data acquisition unit 510.

FIG. 7 is an exemplary flow chart illustrating an embodiment of a method 700 for fluid sensing. The method 700 begins in block 710, where a reading session is initiated, and in block 720 a sensing line pair associated with a sensing region 150 is selected. For example, referring to FIGS. 1a, 1c and 1e the line “A” and line “a” may be selected, which are associated with sensing region 150Aa.

In block 730, the sensing region 150 is read via the selected sensor pair. For example, a conductance may be measured at the sensing region 150Aa via line “A” and line “a.” In block 740, sensed data is associated with a sensing region identifier and stored. Data may be stored in a matrix, table, array or via any other suitable data storage method. In block 750 a determination is made whether the sensing session is complete, and if so, the method 700 ends in block 799; however, if the sensing session is not complete then the method 700 cycles back to block 720.

For example, it may be desirable to read some or all of the sending regions 150 of a moisture sensing array 100, during a sensing session so that the set of readings can be used to quantify and sense fluid across the sensing array 100. A sensing session comprising a plurality of selected sensing regions 150 may have a sensing order selected randomly or may be pre-selected. In some embodiments, the sensing order may be uniform, such as up or down rows, or the like. In further embodiments, a sensing order may be non-uniform. In the context of FIG. 7, a sensing session will read all sensing regions 150 in a sensing order or randomly, and the sensing session will end when all desired sensing regions 150 have been read. Accordingly, selecting a sensor pair associated with a sensor region in block 720 may include selecting a sequential sensing regions 150 from a list, selecting random sensing regions from a set of unread desired sensing regions or the like.

In some embodiments, reading a sensor may be binary or may provide for a gradient of values. For example, binary sensing may comprise a determination of whether a threshold fluid limit has been met, and if so, fluid is indicated as being present, whereas if the threshold is not met, then the fluid is indicated as being not present.

FIG. 8 is an exemplary flow chart illustrating an embodiment of a method 800 for calibrating a fluid sensor 100. The method begins in block 810, where the conductance of an array 100 is sensed at a dry state. For example, the conductance of the array 100 may be sensed via the sensing method 700 of FIG. 7. In some embodiments, other electrical characteristics such as resistance or capacitance may be measured in addition or alternatively.

Returning to FIG. 8, the sensed array data is stored in block 820, and in block 830, a total sum of the sensed conductance is computed and stored. In block 840, a volume of liquid is introduced to the array 100 and a time period is allowed to lapse, which provides for liquid settling in block 850. A settling time may be chosen based on the properties of various components of an array 100, including the buffer layer 160, conducting lines 110, 130, the fluid layer 120, or the like.

In block 860, array conductances are sensed in a wet state and stored, and in block 870, a total sum of the sensed conductances is computed and stored. In decision block 880, a determination is made whether additional wet calibration points are desired, and if so, the method 800 cycles back to block 840, where a further volume of liquid is introduced to the array 100. However, if no further additional wet calibration points are desired, then the method 800 continues to block 890 where a transfer curve of the sums of conductance is generated, and in block 899, the method 800 is done.

For example, in various embodiments, it may be desirable generate a transfer function that indicates the array's sum of conductance in a dry state and in a plurality of wet states. The total sum of conductance can be calculated with the array 100 in a dry state in block 830, and sequential volumes of liquid can be added to the array 100 to generate a set of total sum conductances at various volumes of liquid. In some embodiments, the amount of liquid introduced at each successive introduction may be constant or may be variable. For example, 5 mL may be added each time, or increasing or decreasing amounts of liquid may be added sequentially as desired.

One example of a transfer function is a linear model polynomial having the form T₁(x)=p₁*x+p₂, where x is the conductance is computed using total sum of conductance f₁(m, n). In such an example, coefficients (with 95% confidence) may be p₁=0.00255 (0.002362, 0.002739) and p₂=−5.141 (−6.828, −3.453). In some embodiments, the transfer function may be embodied in an equation or a lookup-table. Additionally, various embodiments provide for transfer functions of any order, type, or family. One embodiment of a transfer curve is sum of conductance vs. liquid volume (e.g., T₁ (mL, Siemens)).

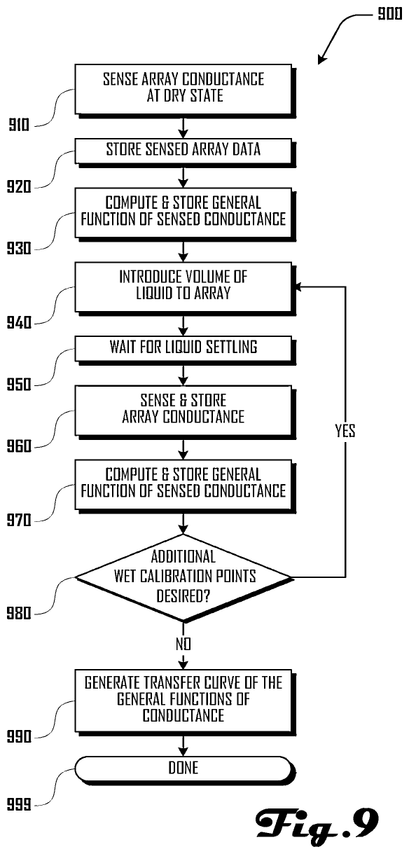

FIG. 9 is an exemplary flow chart illustrating another embodiment of a method 900 for calibrating a fluid sensor 100. The method 900 begins in block 910, where the conductance of an array 100 is sensed at a dry state. For example, the conductance of an array 100 may be sensed via the sensing method 700 of FIG. 7. In some embodiments, other electrical characteristics such as resistance or capacitance may be measured in addition or alternatively.

Returning to FIG. 9, the sensed array data is stored in block 920, and in block 930, a general function of the sensed conductance is computed and stored. In block 840, a volume of liquid is introduced to the array 100 and a time period is allowed to lapse, which provides for liquid settling in block 950. A settling time may be chosen based on the properties of various components of an array 100, including the buffer layer 160, conducting lines 110, 130, the fluid layer 120, or the like.

In block 960, array conductances are sensed in a wet state and stored, and in block 970, a general function of the sensed conductance is computed and stored. In decision block 980, a determination is made whether additional wet calibration points are desired, and if so, the method 900 cycles back to block 940, where a further volume of liquid is introduced to the array 100. However, if no further additional wet calibration points are desired, then the method 900 continues to block 990 where a transfer curve of the general functions (e.g., f₂(m, n)) is generated, and in block 999, the method 900 is done.

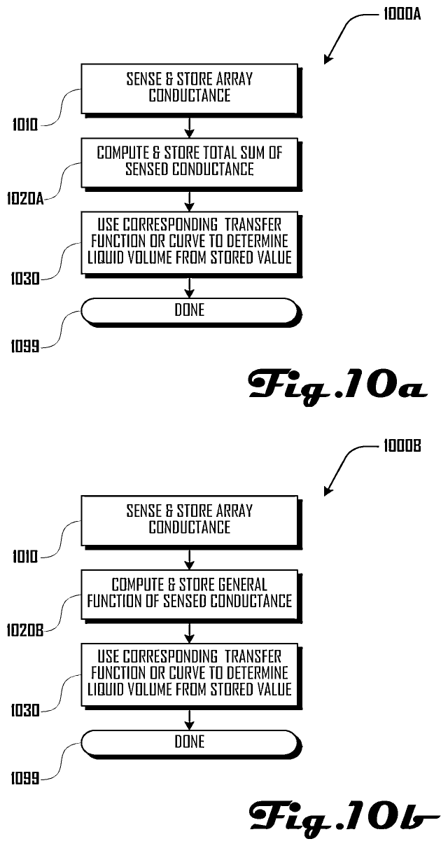

FIGS. 10a and 10b depict methods 1000A, 1000B of determining fluid volume in accordance with a first and second embodiment. The methods 1000A, 1000B begin in block 1010, where array conductance is sensed and stored, which may be performed according to the method 700 of FIG. 7, or the like.

FIG. 10a depicts a method 1000A wherein a total sum of sensed conductance is computed and stored, in block 1020A. FIG. 10b depicts a method 1000B wherein a general function of the sensed conductance is computed and stored, in block 1020B. In block 1030, the stored value is compared to a corresponding transfer function or curve to determine a value for volume of liquid, and the methods 1000A, 1000B are done in block 1099.

As discussed relation to FIGS. 7 and 8, a transfer curve or function may be generated based on total sum of conductances vs. liquid volume, or may be generated based on general function of conductances vs. liquid volume. Accordingly, one or both of such transfer curves or functions may be used to then determine a value for liquid volume based on sensed conductance of an array 100.

In further embodiments, a moisture sending array 100 may be used to calculate a surface area of array 100 where fluid is present or absent at a given threshold. For example, data obtained from the array 100 can be filtered to identify sensing regions 150 where fluid is detected at a threshold level, and this can be converted into a value for surface area of the array 100 with fluid present, by assigning a surface area value to each sensing region 150 where fluid is detected at a threshold level. Additionally, in some embodiments, such a surface area calculation may be combined with a volume calculation (e.g., FIG. 10a, 10b) to provide a value for volume of fluid in a given surface area.

Additionally, in various embodiments an array 100 may be used to determine the identity of a fluid present in the array 100 or determine the type or class of fluid present in the array 100. For example, a determination may be made whether the a fluid present is a gas or liquid; whether the fluid present is hydrophobic or hydrophilic; whether the fluid is water-based; whether the fluid comprises urine; whether the fluid comprises sweat; or the like.

For example, the variation in the conductivity of different liquids can provide the ability for the array 100 to sense and identify contact between a liquid and one or more sensing regions 150. Conductivity can also be measured based on the material in which the sensor array 100 is contained when moisture is detected. The array 100 can also measure both instantly and over time, values for viscosity, permeability, and conductivity, to identify a liquid. Control values for certain liquids can also be established such that the array compares real-time data with reference values. Individual analyses of liquid for identification can also be combined with surface area and volume measurements above, plus other standard parameters such as temperature, pressure, and motion.

The described embodiments are susceptible to various modifications and alternative forms, and specific examples thereof have been shown by way of example in the drawings and are herein described in detail. It should be understood, however, that the described embodiments are not to be limited to the particular forms or methods disclosed, but to the contrary, the present disclosure is to cover all modifications, equivalents, and alternatives.

What is claimed is:

1. A moisture sensing array comprising:
a first set of spaced apart and substantially parallel conducting lines extending in a first direction;
a second set of spaced apart and substantially parallel conducting lines extending in a second direction substantially perpendicular to the first direction, each of the conducting lines of first set disposed proximate to each of the conducing lines of the second set at a sensing region, and defining a sensing array comprising a plurality of sensing regions; and
a fluid layer disposed between the first and second set of conducting lines at each of the plurality of sensing regions.

2. The moisture sensing array of claim 1, further comprising a fluid barrier layer disposed on the second set of conducting lines.

3. The moisture sensing array of claim 2, further comprising a buffer layer disposed on the first set of conducting lines, with the first and second set of conducting lines and plurality of sensing regions disposed between the buffer layer and the fluid barrier layer.

4. The moisture sensing array of claim 1, wherein the fluid layer comprises a material that changes one of resistive properties, capacitive properties, and inductive properties when exposed to a fluid.

5. The moisture sensing array of claim 1, wherein the array defines a substantially planar flexible sheet.

6. The moisture sensing array of claim 1, wherein the array may comprise a portion of one of bedding, a diaper, a bandage, pants, a shirt, a hat, socks, and gloves.

7. The moisture sensing array of claim 1, wherein the fluid layer comprises a polyaniline-based conducting polymer having an acid dopant.

8. The moisture sensing array of claim 1, wherein the fluid layer comprises a salt.

9. A method of calibrating a moisture sensing array comprising:
providing a moisture sensing array comprising:
a first set of spaced apart conducting lines extending in a first direction;
a second set of spaced apart conducting lines extending in a second direction substantially perpendicular to the first direction, each of the conducting lines of first set disposed proximate to each of the conducing lines of the second set at a sensing region, and defining a sensing array comprising a plurality of sensing regions; and
a fluid layer disposed between the first and second set of conducting lines at each of the plurality of sensing regions;
sensing the conductance at a set of the plurality of sensing regions;
storing the sensed conductances in a first dry conductance set;
computing and storing one of a first dry total sum and a first dry general function of the first dry conductance set;
introducing a first volume of fluid to the fluid layer;
waiting for a first liquid setting interval;
sensing the conductance at a set of the plurality of sensing regions;
storing the sensed conductances in a first wet conductance set;
computing and storing one of a first wet total sum and a first wet general function of the first wet conductance set; and
generating a transfer curve comprising one of:
the first dry total sum and the first wet total sum; and
the first dry general function and the first wet general function.

10. The method of claim 9, further comprising:
introducing a second volume of fluid to the fluid layer;
waiting for a second liquid setting interval;
sensing the conductance at a set of the plurality of sensing regions;
storing the sensed conductances in a second wet conductance set;
computing and storing one of a second wet total sum and a second wet general function of the second wet conductance set; and
generating a transfer curve comprising one of:
the first dry total sum and the first and second wet total sum; and
the first dry general function and the first and second wet general function.

11. The method of claim 9, wherein the first liquid settling time is selected based on one or more properties of the fluid layer.

12. The method of claim 9, wherein the first liquid settling time is selected based on one or more properties of the conducting lines.

13. The method of claim 9, wherein moisture sensing array further comprises a buffer layer disposed on one of the first and second set of conducting lines.

14. The method of claim 13, wherein the first liquid settling time is selected based on one or more properties of the buffer layer.

15. The method of claim 9, wherein the sensing of the conductances is digital sensing.

16. The method of claim 9, wherein the sensing of the conductances is analog sensing.
